(19) United States
(12) Patent Application Publication
(10) Pub. No.: US 2026/0089897 A1
(43) Pub. Date: Mar. 26, 2026

(54) Liquid Cooled Power Conversion System

(71) Applicant: AA Power Inc., Boston, MA (US)

(72) Inventor: Qun Lu, Lexington, MA (US)

(21) Appl. No.: 19/319,575

(22) Filed: Sep. 4, 2025

Related U.S. Application Data
(60) Provisional application No. 63/698,543, filed on Sep. 24, 2024.

(51) Int. Cl. H05K 7/20; H02M 3/00; H02M 3/335

(52) U.S. Cl. CPC H05K 7/20927; H02M 3/003; H02M 3/33576; H05K 7/209

(57) ABSTRACT

A system includes a first unregulated power converter connected between an input voltage bus and an output voltage bus, wherein the first unregulated power converter comprises a plurality of first power switches, a second unregulated power converter connected between the input voltage bus and the output voltage bus, wherein the second unregulated power converter comprises a plurality of second power switches, and a liquid cooling system configured to cool the plurality of first power switches and the plurality of second power switches to achieve balanced current sharing between the first unregulated power converter and the second unregulated power converter.

### PRIORITY

This application claims the benefit of U.S. Provisional Application No. 63/698,543, filed on Sep. 24, 2024, entitled “Liquid Cooled Power Conversion System,” which application is hereby incorporated herein by reference.

### TECHNICAL FIELD

The present invention relates to a liquid cooled power conversion system, and in particular to a system and method for achieving current sharing in a power conversion system comprising a plurality of unregulated power converters connected in parallel.

### BACKGROUND

As technologies further advance, a modern data center is equipped with numerous high-performance processors such as graphics processing units (GPUs). The processors are designed to handle intensive computing workloads such as artificial intelligence (AI) training, machine learning, and complex simulations. These GPUs, often organized into high-density racks, deliver exceptional parallel processing power, enabling the rapid analysis and processing of vast amounts of data.

In a data center, a processor is powered by a power conversion system. This power conversion system is connected between the electric grid and the processor. The power conversion system is configured to convert the ac voltage of the electric grid into a voltage suitable for driving the processor. In some power conversion systems, multiple power converters are connected in parallel to supply power to the load. In these power conversion systems, the goal is to ensure that each converter shares the load current equally, or according to their design capacity, to prevent overloading any single unit. Current sharing is crucial for system reliability, efficiency, and longevity. A variety of control methods have been employed to achieve current sharing. The variety of control methods include voltage droop control, master-slave control, active current sharing control, average current mode control, centralized control and the like. In some applications, the power provided to the processor is from a plurality of unregulated power converters connected in parallel. Unregulated power converters lack a feedback loop that adjusts their output based on load conditions. When multiple unregulated power converters are connected in parallel, small differences in their output voltages can cause unequal current distribution. For example, an unregulated power converter with a higher output voltage will deliver more current, while others with slightly lower voltages will deliver less current or may not contribute at all. This imbalance can lead to overloading the unregulated power converter having a higher output voltage, potentially causing it to overheat or fail.

In operation, heat can cause unbalanced current sharing in unregulated power converters connected in parallel due to the temperature-dependent behavior of the electrical components inside the unregulated power converters. Many components (e.g., power switches) in an unregulated power converter, have temperature coefficients that cause their electrical properties to change as they heat up. For example, as temperature increases, the on-state resistance of power switches increases. This leads to higher voltage drops for the same current, causing the unregulated power converter to output less current as it heats up. In a power conversion system comprising a plurality of unregulated power converters, when one unregulated power converter heats up more than another, its output voltage may drop, causing it to supply less current, leading to an imbalance in current sharing. It is desirable to have a system and method to achieve current sharing in a power conversion system comprising a plurality of unregulated power converters connected in parallel. The present disclosure addresses this need.

### SUMMARY

These and other problems are generally solved or circumvented, and technical advantages are generally achieved, by preferred embodiments of the present disclosure which provide a system and method for achieving current sharing in a power conversion system comprising a plurality of unregulated power converters connected in parallel.

In accordance with an embodiment, a system comprises a first unregulated power converter connected between an input voltage bus and an output voltage bus, wherein the first unregulated power converter comprises a plurality of first power switches, a second unregulated power converter connected between the input voltage bus and the output voltage bus, wherein the second unregulated power converter comprises a plurality of second power switches, and a liquid cooling system configured to cool the plurality of first power switches and the plurality of second power switches to achieve balanced current sharing between the first unregulated power converter and the second unregulated power converter.

In accordance with another embodiment, a method comprises providing a first unregulated power converter connected between an input voltage bus and an output voltage bus, wherein the first unregulated power converter comprises a plurality of first power switches, providing a second unregulated power converter connected between the input voltage bus and the output voltage bus, wherein the second unregulated power converter comprises a plurality of second power switches, and circulating liquid to cool the plurality of first power switches and the plurality of second power switches to achieve balanced current sharing between the first unregulated power converter and the second unregulated power converter.

In accordance with yet another embodiment, a method comprises providing a first unregulated power converter connected between an input voltage bus and an output voltage bus, wherein the first unregulated power converter comprises a plurality of first power switches, providing a second unregulated power converter connected between the input voltage bus and the output voltage bus, wherein the second unregulated power converter comprises a plurality of second power switches, circulating liquid to cool the plurality of first power switches through a plurality of first liquid pipes, circulating liquid to cool the plurality of second power switches through a plurality of second liquid pipes, and dynamically adjusting a first liquid flow speed in the plurality of first liquid pipes and a second liquid flow speed in the plurality of second liquid pipes to achieve balanced current sharing between the first unregulated power converter and the second unregulated power converter.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a power conversion system comprising a plurality of unregulated power converters connected between an input voltage bus and an output voltage bus in accordance with various embodiments of the present disclosure;

FIG. 2 illustrates a schematic diagram of the unregulated power converter shown in FIG. 1 in accordance with various embodiments of the present disclosure;

FIG. 3 illustrates a first implementation of the cooling arrangement of the unregulated power converters in accordance with various embodiments of the present disclosure;

FIG. 4 illustrates a second implementation of the cooling arrangement of the unregulated power converters in accordance with various embodiments of the present disclosure;

FIG. 5 illustrates a third implementation of the cooling arrangement of the unregulated power converters in accordance with various embodiments of the present disclosure;

FIG. 6 illustrates a fourth implementation of the cooling arrangement of the unregulated power converters in accordance with various embodiments of the present disclosure;

FIG. 7 illustrates a fifth implementation of the cooling arrangement of the unregulated power converters in accordance with various embodiments of the present disclosure;

FIG. 8 illustrates a sixth implementation of the cooling arrangement of the unregulated power converters in accordance with various embodiments of the present disclosure;

FIG. 9 illustrates a first implementation of cooling a plurality of unregulated LLC power converters in accordance with various embodiments of the present disclosure;

FIG. 10 illustrates a second implementation of cooling a plurality of unregulated LLC power converters in accordance with various embodiments of the present disclosure;

FIG. 11 illustrates a third implementation of cooling a plurality of unregulated LLC power converters in accordance with various embodiments of the present disclosure;

FIG. 12 illustrates a fourth implementation of cooling a plurality of unregulated LLC power converters in accordance with various embodiments of the present disclosure;

FIG. 13 illustrates a fifth implementation of cooling a plurality of unregulated LLC power converters in accordance with various embodiments of the present disclosure;

FIG. 14 illustrates a sixth implementation of cooling a plurality of unregulated LLC power converters in accordance with various embodiments of the present disclosure;

FIG. 15 illustrates a flow chart of a method for cooling the power conversion system shown in FIG. 1 in accordance with various embodiments of the present disclosure;

FIG. 16 illustrates an implementation of cooling two unregulated LLC power converters in accordance with various embodiments of the present disclosure;

FIG. 17 illustrates an implementation of cooling a plurality of unregulated LLC power converters in accordance with various embodiments of the present disclosure; and

FIG. 18 illustrates a flow chart of a method for cooling the power conversion system shown in FIG. 16 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to preferred embodiments in a specific context, namely a system and method for achieving current sharing in a power conversion system comprising a plurality of unregulated power converters connected in parallel. The disclosure may also be applied, however, to a variety of power conversion systems. Hereinafter, various embodiments will be explained in detail with reference to the accompanying drawings.

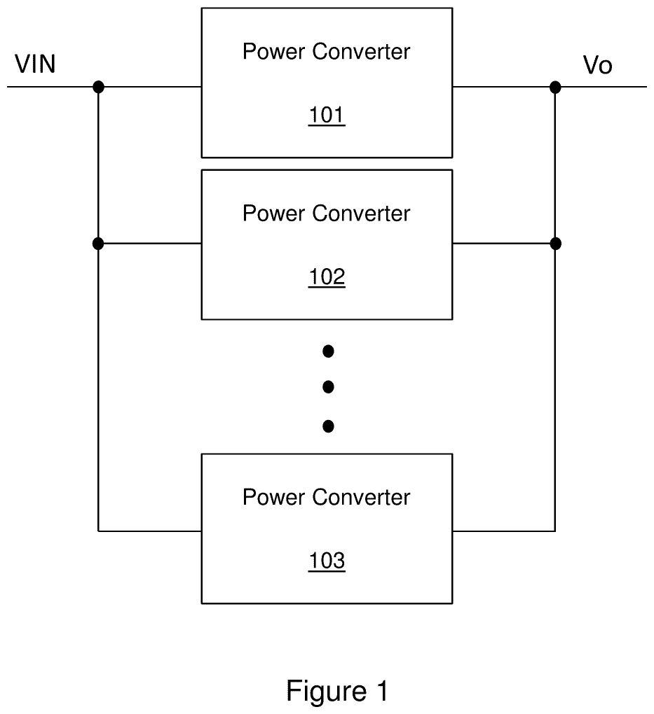

FIG. 1 illustrates a block diagram of a power conversion system comprising a plurality of unregulated power converters connected between an input voltage bus and an output voltage bus in accordance with various embodiments of the present disclosure. As shown in FIG. 1, a first unregulated power converter 101 is connected between an input voltage bus VIN and an output voltage bus Vo. The first unregulated power converter 101 comprises a plurality of first power switches. A second unregulated power converter 102 is connected between the input voltage bus VIN and the output voltage bus Vo. The second unregulated power converter 102 comprises a plurality of second power switches. A third unregulated power converter 103 is connected between the input voltage bus VIN and the output voltage bus Vo. The third unregulated power converter 103 comprises a plurality of third power switches. As indicated by the dots in FIG. 1, a plurality of unregulated power converters is placed between the second unregulated power converter 102 and the third unregulated power converter 103.

A load (not shown) is coupled to the output voltage bus Vo. In some embodiments, the load comprises a plurality of crypto miners in a crypto farm. Each crypto miner may comprise a plurality of graphics processing units (GPUs), a plurality of application-specific integrated chips (ASICs), any combinations thereof and the like.

In some embodiments, each unregulated power converter shown in FIG. 1 is an inductor-inductor-capacitor (LLC) resonant converter configured to operate at a fixed duty cycle (e.g., 50%). In alternative embodiments, depending on different applications and design needs, each unregulated power converter shown in FIG. 1 may be implemented as an isolated power converter such as a forward converter, a flying converter, a fly-forward converter, a full bridge converter, a half bridge converter, any combinations thereof and the like.

In operation, power switches of the plurality of unregulated power converters generate heat. A liquid cooling system is configured to cool the power switches to achieve balanced current sharing among the plurality of unregulated power converters. In particular, power switches of each unregulated power converter are mounted on a corresponding heat sink. The heat is conducted to the corresponding heat sink from the power switches. The large surface area of the heat sink facilitates efficient heat transfer. A plurality of liquid pipes is connected to heat sinks. The heat sinks and pipes form a cooling system. A pump pushes coolant (e.g., a suitable liquid such as water) through the system, flowing through the heat sinks. The heat from the power switches is absorbed by the coolant. The heated coolant then travels through the pipe to a radiator, where it is cooled. Once the liquid is cooled in the radiator, it is pumped back to the heat sinks to absorb more heat, continuing the cycle. Liquid has a higher heat capacity than air, making it more effective at absorbing and transferring heat.

In operation, the cooling system maintains a uniform temperature across the power switches of the plurality of unregulated power converters. This consistent temperature ensures that the power switches have the same on-resistance, resulting in identical voltage drops for equal currents. These matching voltage drops help to achieve current sharing among the plurality of unregulated power converters.

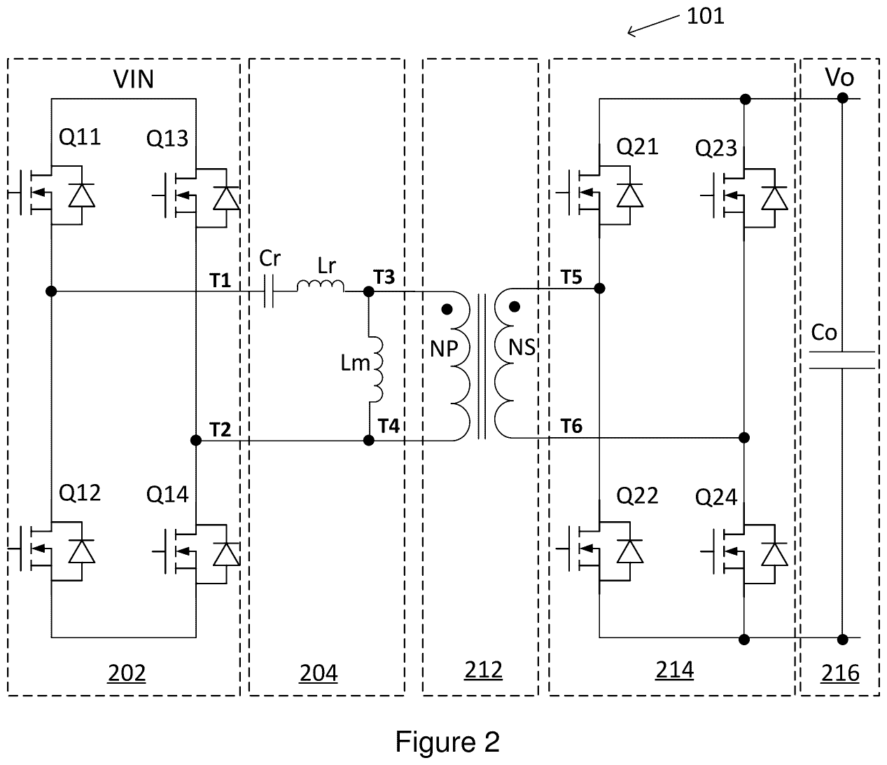

FIG. 2 illustrates a schematic diagram of the unregulated power converter shown in FIG. 1 in accordance with various embodiments of the present disclosure. In some embodiments, the unregulated power converter (e.g., 101) is implemented as an LLC resonant converter. As shown in FIG. 2, the LLC resonant converter comprises a switch network 202, a resonant tank 204, a transformer 212, a rectifier 214 and an output filter 216. As shown in FIG. 2, the switch network 202, the resonant tank 204, the transformer 212, the rectifier 214 and the output filter 216 are coupled to each other and connected in cascade between the input voltage bus VIN and the output voltage bus Vo.

The switch network 202 includes four switching elements, namely Q11, Q12, Q13 and Q14. Throughout the description, the switch network 202 is alternatively referred to as a primary switch network.

As shown in FIG. 2, a first pair of switching elements Q11 and Q12 are connected in series between the input voltage bus VIN and a primary ground. A second pair of switching elements Q13 and Q14 are connected in series between the input voltage bus VIN and the primary ground. The common node of the switching elements Q11 and Q12 is coupled to a first input terminal T1 of the resonant tank 204. Likewise, the common node of the switching elements Q13 and Q14 is coupled to a second input terminal T2 of the resonant tank 204.

FIG. 2 further illustrates the resonant tank 204 is coupled between the switch network 202 and the transformer 212. The resonant tank 204 is formed by a series resonant inductor Lr, a series resonant capacitor Cr and a parallel inductance Lm. As shown in FIG. 2, the series resonant inductor Lr and the series resonant capacitor Cr are connected in series and further coupled to the primary side of the transformer 212.

It should be noted while FIG. 2 shows the series resonant inductor Lr is an independent component, the series resonant inductor Lr may be replaced by the leakage inductance of the transformer 212. In other words, the leakage inductance (not shown) may function as the series resonant inductor Lr.

It should further be noted while FIG. 2 shows the resonant tank is placed on the primary side of the LLC resonant converter, this diagram is merely an example. A person skilled in the art will recognize many variations, alternatives and modifications. For example, the resonant tank may be placed on the secondary side. Furthermore, the resonant tank may be placed on both sides of the transformer 212.

The transformer 212 has a primary winding NP and a secondary winding NS. The primary winding is coupled to terminals T3 and T4 of the resonant tank 204 as shown in FIG. 2. The secondary winding is coupled to the output of the LLC resonant converter through the rectifier 214, which is a full-bridge rectifier comprising switches Q21, Q22, Q23 and Q24. Throughout the description, the rectifier 214 is alternatively referred to as a secondary switch network.

As shown in FIG. 2, switches Q21 and Q22 are connected in series and further coupled between two terminals of the output capacitor Co. Switches Q23 and Q24 are connected in series and further coupled between the two terminals of the output capacitor Co. The common node T5 of the switches Q21 and Q22 is coupled to a first terminal of the secondary winding of the transformer 212. Likewise, the common node T6 of the switches Q23 and Q24 is coupled to a second terminal of the secondary winding of the transformer 212.

It should be noted that the transformer structure shown in FIG. 2 is merely an example. One person skilled in the art will recognize many alternatives, variations and modification. For example, the secondary side of the transformer 212 may be a center tapped transformer winding. As a result, the secondary side may employ a synchronous rectifier formed by two switching elements. The operation principle of a synchronous rectifier coupled to a center tapped transformer winding is well known, and hence is not discussed in further detail herein to avoid repetition.

It should further be noted that the power topology of the LLC resonant converter may be not only applied to the rectifier as shown in FIG. 2, but also applied to other secondary configurations, such as voltage doubler rectifiers, current doubler rectifiers, any combinations thereof and/or the like.

In operation, when the switching frequency of the LLC resonant converter is equal to the resonant frequency of the resonant tank of the LLC resonant converter, the LLC resonant converter may have a unity system gain. On the other hand, when the switching frequency of the LLC resonant converter is higher than the resonant frequency, the LLC resonant converter is of a lower system gain.

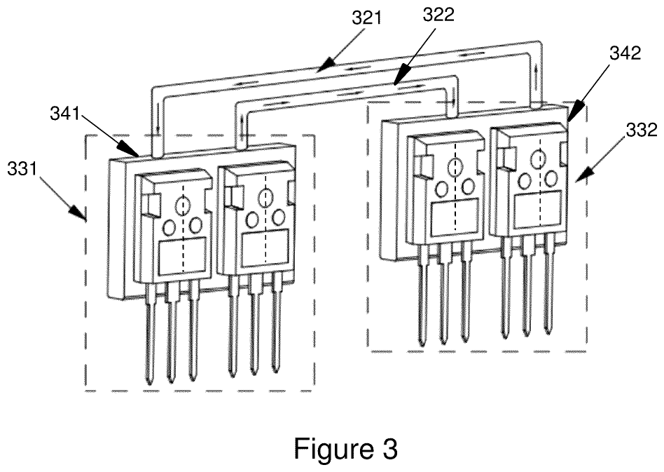

Referring back to FIG. 1, the power conversion system comprises a plurality of unregulated power converters with similar operating principles and cooling mechanisms. For simplicity, FIGS. 3-8 depict only two unregulated power converters to demonstrate how the cooling system is designed to maintain a uniform temperature across all the unregulated power converters.

FIG. 3 illustrates a first implementation of the cooling arrangement of the unregulated power converters in accordance with various embodiments of the present disclosure. As shown in FIG. 3, the plurality of first power switches 331 of the first unregulated power converter 101 is mounted on a first heat sink 341. The plurality of second power switches 332 of the second unregulated power converter 102 is mounted on a second heat sink 342. A plurality of liquid pipes is connected between the first heat sink 341 and the second heat sink 342. The plurality of liquid pipes comprises a first liquid pipe 321 through which liquid flows from the second heat sink 342 to the first heat sink 341, and a second liquid pipe 322 through which liquid flows from the first heat sink 341 to the second heat sink 342.

In some embodiments, cooling efficiency is further enhanced by arranging the liquid pipes to align with specific power switch locations within the heat sinks. A portion of the first liquid pipe 321 is in the first heat sink 341 and underneath the left power switch on the first heat sink 341. As indicated by dashed line over the left power switch on the first heat sink 341, the midline of the portion of the first liquid pipe 321 in the first heat sink 341 is aligned with the midline of the left power switch on the first heat sink 341. Likewise, a portion of the second liquid pipe 322 is in the first heat sink 341 and underneath the right power switch on the first heat sink 341. As indicated by dashed line over the right power switch on the first heat sink 341, the midline of the portion of the second liquid pipe 322 in the first heat sink 341 is aligned with the midline of the right power switch on the first heat sink 341.

A portion of the second liquid pipe 322 is in the second heat sink 342 and underneath the left power switch on the second heat sink 342. As indicated by dashed line over the left power switch on the second heat sink 342, the midline of the portion of the second liquid pipe 322 in the second heat sink 342 is aligned with the midline of the left power switch on the second heat sink 342. A portion of the first liquid pipe 321 is in the second heat sink 342 and underneath the right power switch on the second heat sink 342. As indicated by dashed line over the right power switch on the second heat sink 342, the midline of the portion of the first liquid pipe 321 in the second heat sink 342 is aligned with a midline of the right power switch on the second heat sink 342.

One advantageous feature of having the pipe line and power switch alignment is that this arrangement ensures better thermal coupling between the cooling liquid and the power switches, thereby improving heat transfer and overall cooling performance.

In operation, cooling liquid circulates between the first heat sink 341 and the second heat sink 342 via the liquid pipes 321 and 322. This circulation establishes thermal coupling between the two unregulated power converters, promoting a substantially uniform temperature across the power switches of both unregulated power converters. By maintaining similar operating temperatures, the on-resistances of the power switches are equalized, which in turn facilitates balanced current sharing between the first unregulated power converter 101 and the second unregulated power converter 102.

It should be noted that FIG. 3 illustrates only two unregulated power converters of a power conversion system that may include hundreds of such unregulated power converters. The number of unregulated power converters illustrated herein is limited solely for the purpose of clearly illustrating the inventive aspects of the various embodiments. The present invention is not limited to any specific number of unregulated power converters.

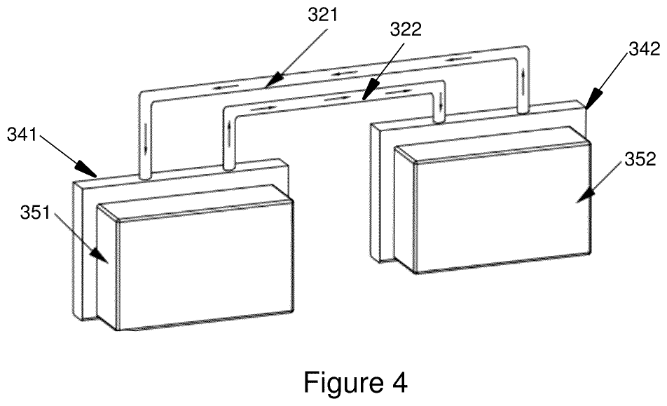

FIG. 4 illustrates a second implementation of the cooling arrangement of the unregulated power converters in accordance with various embodiments of the present disclosure. As shown in FIG. 4, the first unregulated power converter 101 is packaged in a first power module 351. The first power module 351 is mounted on the first heat sink 341. In some embodiments, a good thermal interface is provided between the first power module 351 and the first heat sink 341 such that the temperature of the first power module 351 is substantially similar to the temperature of the first heat sink 341. Furthermore, the power switches of the first unregulated power converter 101 are directly mounted on the bottom of the first power module 351. The power switches have a good thermal coupling with the first heat sink 341 through the bottom of the first power module 351. In other words, the temperature of the power switches in the first power module 351 is substantially similar to the temperature of the first heat sink 341.

The second unregulated power converter 102 is packaged in a second power module 352. The second power module 352 is mounted on the second heat sink 342. In some embodiments, a good thermal interface is provided between the second power module 352 and the second heat sink 342 such that the temperature of the second power module 352 is substantially similar to the temperature of the second heat sink 342. Furthermore, the power switches of the second unregulated power converter 102 are directly mounted on the bottom of the second power module 352. The power switches have a good thermal coupling with the second heat sink 342 through the bottom of the second power module 352. In other words, the temperature of the power switches in the second power module 352 is substantially similar to the temperature of the second heat sink 342.

A plurality of liquid pipes is connected between the first heat sink 341 and the second heat sink 342. The plurality of liquid pipes comprises a first liquid pipe 321 through which liquid flows from the second heat sink 342 to the first heat sink 341, and a second liquid pipe 322 through which liquid flows from the first heat sink 341 to the second heat sink 342.

In operation, cooling liquid circulates between the first heat sink 341 and the second heat sink 342 via the liquid pipes 321 and 322. This circulation establishes thermal coupling between the two unregulated power converters, promoting a substantially uniform temperature across the power switches of both unregulated power converters. By maintaining similar operating temperatures, the on-resistances of the power switches are equalized, which in turn facilitates balanced current sharing between the first unregulated power converter 101 and the second unregulated power converter 102.

It should be noted that FIG. 4 illustrates only two unregulated power converters of a power conversion system that may include hundreds of such unregulated power converters. The number of unregulated power converters illustrated herein is limited solely for the purpose of clearly illustrating the inventive aspects of the various embodiments. The present invention is not limited to any specific number of unregulated power converters.

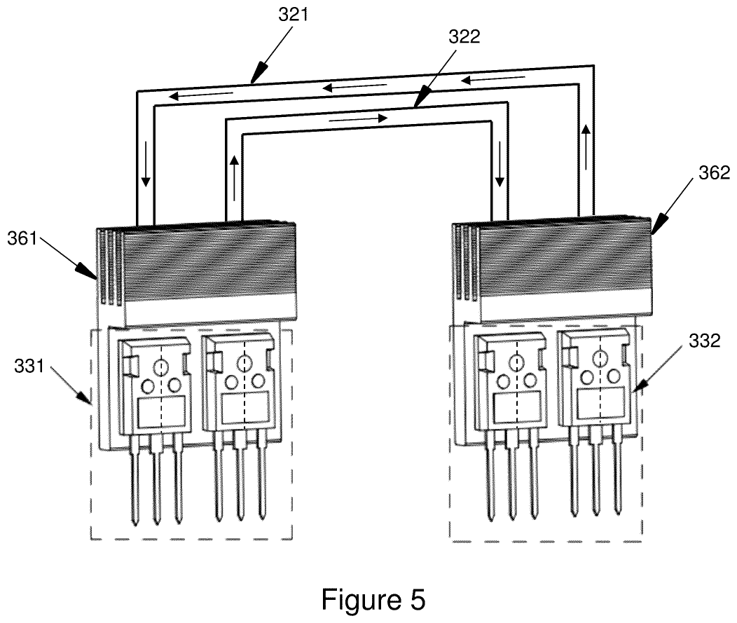

A finger heat sink is a type of heat sink designed with multiple thin and elongated fins that resemble fingers, providing a large surface area to effectively dissipate heat from electronic components. The finger-like design creates a significantly larger surface area compared to a flat heat sink, allowing for more efficient heat dissipation. The finger heat sink is made of suitable materials such as aluminum, copper and the like. FIGS. 5-8 depict that heat generation components are mounted on finger heat sinks, and liquid pipes are connected to the finger heat sinks. In operation, the finger heat sink based cooling system is designed to maintain a uniform temperature across all the unregulated power converters.

FIG. 5 illustrates a third implementation of the cooling arrangement of the unregulated power converters in accordance with various embodiments of the present disclosure. As shown in FIG. 5, the plurality of first power switches 331 of the first unregulated power converter 101 is mounted on a first finger heat sink 361. The plurality of second power switches 332 of the second unregulated power converter 102 is mounted on a second finger heat sink 362. A plurality of liquid pipes is connected between the first finger heat sink 361 and the second finger heat sink 362. The plurality of liquid pipes comprises a first liquid pipe 321 through which liquid flows from the second finger heat sink 362 to the first finger heat sink 361, and a second liquid pipe 322 through which liquid flows from the first finger heat sink 361 to the second finger heat sink 362.

In some embodiments, as indicated by the dashed lines in FIG. 5, the positioning of the liquid pipes within the heat sinks is similar to that described above with reference to FIG. 3. In particular, portions of the liquid pipes are disposed beneath corresponding power switches and oriented substantially along the midlines of those switches, thereby providing better thermal coupling and improved cooling performance.

In operation, cooling liquid circulates between the first finger heat sink 361 and the second finger heat sink 362 via the liquid pipes 321 and 322. This circulation establishes thermal coupling between the two unregulated power converters, promoting a substantially uniform temperature across the power switches of both unregulated power converters. By maintaining similar operating temperatures, the on-resistances of the power switches are equalized, which in turn facilitates balanced current sharing between the first unregulated power converter 101 and the second unregulated power converter 102.

It should be understood that, as in the prior figures, the number of converters illustrated in FIG. 5 is provided for ease of explanation only and is not intended to limit the scope of the present disclosure.

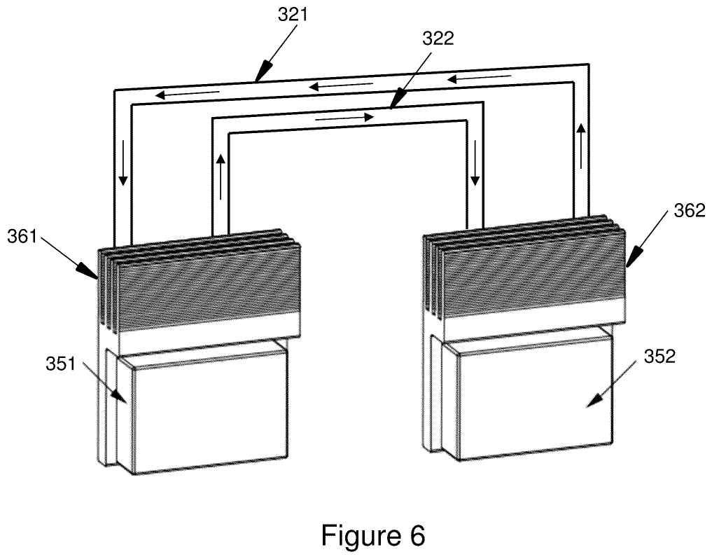

FIG. 6 illustrates a fourth implementation of the cooling arrangement of the unregulated power converters in accordance with various embodiments of the present disclosure. As shown in FIG. 6, the first unregulated power converter 101 is packaged in a first power module 351. The first power module 351 is mounted on the first finger heat sink 361. The second unregulated power converter 102 is packaged in a second power module 352. The second power module 352 is mounted on the second finger heat sink 362. The thermal configuration of the first power module 351 and the second power module 352 is similar to that discussed above with respect to FIG. 4, and hence is not described in detail herein.

A plurality of liquid pipes is connected between the first finger heat sink 361 and the second finger heat sink 362. The plurality of liquid pipes comprises a first liquid pipe 321 through which liquid flows from the second finger heat sink 362 to the first finger heat sink 361, and a second liquid pipe 322 through which liquid flows from the first finger heat sink 361 to the second finger heat sink 362.

In operation, cooling liquid circulates between the first finger heat sink 361 and the second finger heat sink 362 via the liquid pipes 321 and 322. This circulation establishes thermal coupling between the two unregulated power converters, promoting a substantially uniform temperature across the power switches of both unregulated power converters. By maintaining similar operating temperatures, the on-resistances of the power switches are equalized, which in turn facilitates balanced current sharing between the first unregulated power converter 101 and the second unregulated power converter 102.

It should be understood that, as in the prior figures, the number of converters illustrated in FIG. 6 is provided for ease of explanation only and is not intended to limit the scope of the present disclosure.

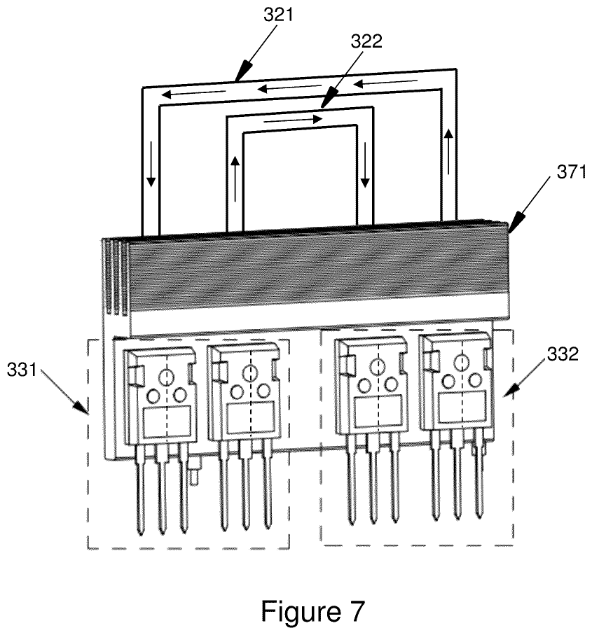

FIG. 7 illustrates a fifth implementation of the cooling arrangement of the unregulated power converters in accordance with various embodiments of the present disclosure. As shown in FIG. 7, the plurality of first power switches 331 of the first unregulated power converter 101 and the plurality of second power switches 332 of the second unregulated power converter 102 are mounted on a finger heat sink 371. A plurality of liquid pipes is connected to the finger heat sink 371. The plurality of liquid pipes comprises a first liquid pipe 321 through which liquid flows from the right side of the finger heat sink 371 to the left side of the finger heat sink 371, and a second liquid pipe 322 through which liquid flows from the left side of the finger heat sink 371 to the right side of the finger heat sink 371.

In some embodiments, as indicated by the dashed lines in FIG. 7, the positioning of the liquid pipes within the heat sinks is similar to that described above with reference to FIG. 3. In particular, portions of the liquid pipes are disposed beneath corresponding power switches and oriented substantially along the midlines of those switches, thereby providing better thermal coupling and improved cooling performance.

In operation, cooling liquid circulates between the right side of the finger heat sink 371 and the left side of the finger heat sink 371 via the liquid pipes 321 and 322. This circulation establishes thermal coupling between the two unregulated power converters, promoting a substantially uniform temperature across the power switches of both unregulated power converters. By maintaining similar operating temperatures, the on-resistances of the power switches are equalized, which in turn facilitates balanced current sharing between the first unregulated power converter 101 and the second unregulated power converter 102.

It should be understood that, as in the prior figures, the number of converters illustrated in FIG. 7 is provided for ease of explanation only and is not intended to limit the scope of the present disclosure.

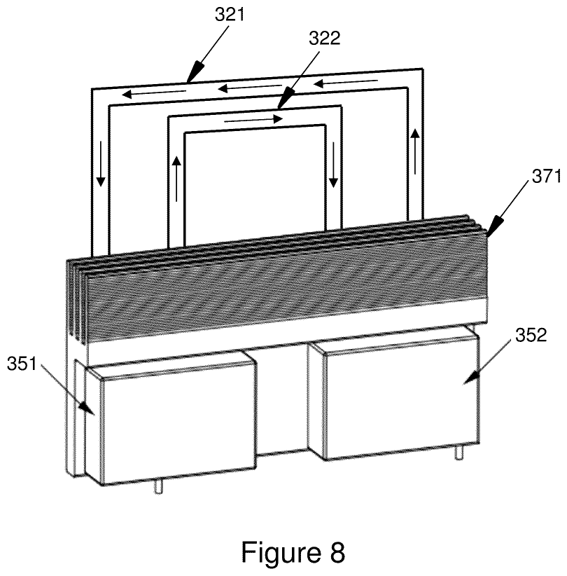

FIG. 8 illustrates a sixth implementation of the cooling arrangement of the unregulated power converters in accordance with various embodiments of the present disclosure. As shown in FIG. 8, the first unregulated power converter 101 is packaged in a first power module 351. The second unregulated power converter 102 is packaged in a second power module 352. The first power module 351 and the second power module 352 are mounted on a finger heat sink 371. The thermal configuration of the first power module 351 and the second power module 352 is similar to that discussed above with respect to FIG. 4, and hence is not described in detail herein.

A plurality of liquid pipes is connected to the finger heat sink 371. The plurality of liquid pipes comprises a first liquid pipe 321 through which liquid flows from the right side of the finger heat sink 371 to the left side of the finger heat sink 371, and a second liquid pipe 322 through which liquid flows from the left side of the finger heat sink 371 to the right side of the finger heat sink 371.

In operation, cooling liquid circulates between the right side of the finger heat sink 371 and the left side of the finger heat sink 371 via the liquid pipes 321 and 322. This circulation establishes thermal coupling between the two unregulated power converters, promoting a substantially uniform temperature across the power switches of both unregulated power converters. By maintaining similar operating temperatures, the on-resistances of the power switches are equalized, which in turn facilitates balanced current sharing between the first unregulated power converter 101 and the second unregulated power converter 102.

It should be understood that, as in the prior figures, the number of converters illustrated in FIG. 8 is provided for ease of explanation only and is not intended to limit the scope of the present disclosure.

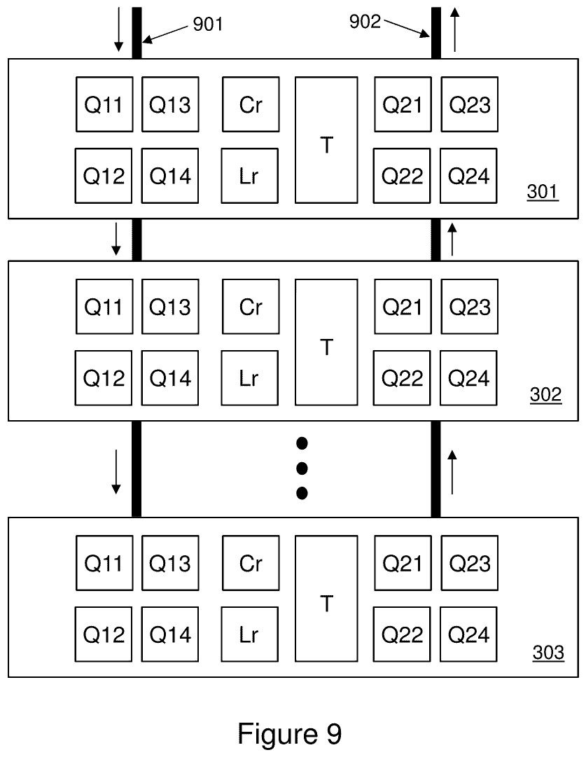

Referring back to FIG. 2, the first unregulated power converter is implemented as a first LLC resonant converter comprising a plurality of first primary switches Q11, Q12, Q13 and Q14, a first resonant tank formed by Cr and Lr, a first transformer and a plurality of first secondary switches Q21, Q22, Q23 and Q24. The second unregulated power converter is implemented as a second LLC resonant converter comprising a plurality of second primary switches Q11, Q12, Q13 and Q14, a second resonant tank formed by Cr and Lr, a second transformer and a plurality of second secondary switches Q21, Q22, Q23 and Q24. FIGS. 9-14 illustrate how the cooling system is designed to maintain a uniform temperature across all the unregulated LLC resonant converters.

FIG. 9 illustrates a first implementation of cooling a plurality of unregulated LLC power converters in accordance with various embodiments of the present disclosure. The plurality of first primary switches, the first resonant tank, the first transformer and the plurality of first secondary switches are mounted on a first heat sink 301. The plurality of second primary switches, the second resonant tank, the second transformer and the plurality of second secondary switches are mounted on a second heat sink 302. The heat generation components of other unregulated LLC power converters are arranged in a similar manner. For example, the heat generation components of the Nth unregulated LLC power converter are mounted on the heat sink 303.

In some embodiments, the heat sinks 301, 302 and 303 are insulated metal substrate type heat sinks that include a single thermally conductive connection layer formed on the heat sink. All heat-generating components mounted on a given heat sink are thermally coupled to one another through this single connection layer, thereby promoting uniform heat spreading and improved cooling performance.

A plurality of liquid pipes is connected to the heat sinks. As indicated by the arrows shown in FIG. 9, liquid circulates through the heat sinks via the plurality of liquid pipes to maintain a uniform temperature across the unregulated LLC power converters.

As shown in FIG. 9, a first liquid pipe 901 of the plurality of liquid pipes is placed at a first equal distance from two adjacent first primary switches (e.g., Q11 and Q13, or Q12 and Q14). A second liquid pipe 902 of the plurality of liquid pipes is placed at a second equal distance from two adjacent first second switches (e.g., Q21 and Q23, or Q22 and Q24). It should be noted that an interconnect liquid pipe (not shown) is placed in the heat sink 303. The interconnect liquid pipe is employed to connect the first liquid pipe 901 and the second liquid pipe 902.

In operation, by cooling the power switches through the liquid pipes and insulated metal substrate heat sinks as described above, the operating temperature of the power switches is maintained at a substantially uniform level across the plurality of unregulated LLC power converters. The uniform temperature results in similar on-resistances of the power switches, which in turn facilitates balanced current sharing among the plurality of unregulated LLC power converters. This improves overall system reliability, reduces the risk of overstressing individual converters, and enhances efficiency in high-power applications.

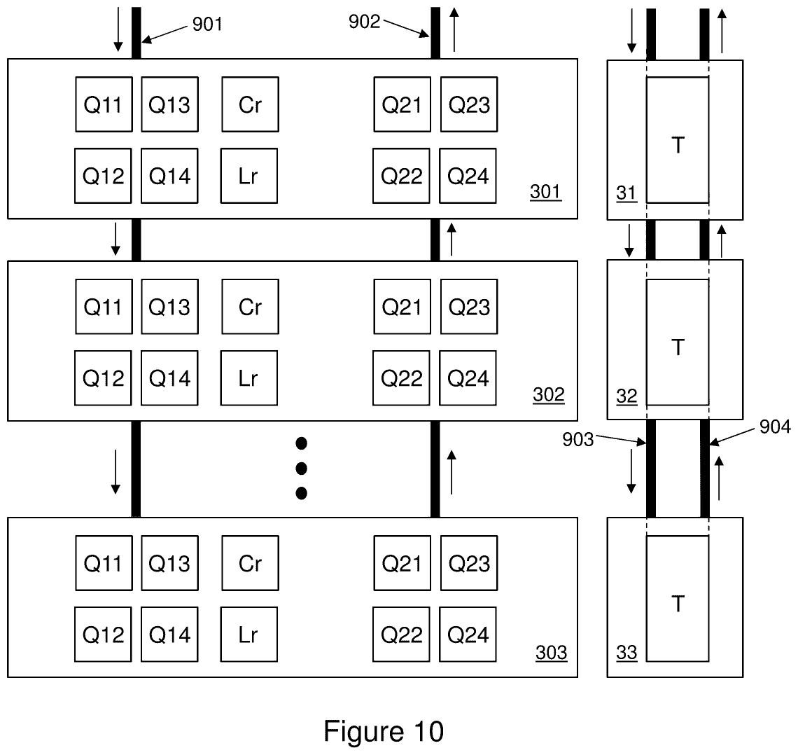

FIG. 10 illustrates a second implementation of cooling a plurality of unregulated LLC power converters in accordance with various embodiments of the present disclosure. The plurality of first primary switches, the first resonant tank and the plurality of first secondary switches are mounted on a first heat sink 301. The first transformer is mounted on a first transformer heat sink 31. The plurality of second primary switches, the second resonant tank and the plurality of second secondary switches are mounted on a second heat sink 302. The second transformer is mounted on a second transformer heat sink 32. The heat generation components of other unregulated LLC power converters are arranged in a similar manner. For example, the primary switches, the resonant tank and the secondary switches of the Nth unregulated LLC power converter are mounted on the heat sink 303. The transformer of the Nth unregulated LLC power converter is mounted on the transformer heat sink 33.

Liquid pipes 901 and 902 are connected to the heat sinks 301, 302 and 303. As indicated by the arrows shown in FIG. 10, liquid circulates through the heat sinks via the liquid pipes 901 and 902 to maintain a first uniform temperature across these heat generation components. Liquid pipes 903 and 904 are connected to the transformer heat sinks 31, 32 and 33. As indicated by the arrows shown in FIG. 10, liquid circulates through the transformer heat sinks via the liquid pipes 903 and 904 to maintain a second uniform temperature across these transformers. In some embodiments, the first uniform temperature is equal to the second uniform temperature.

The positioning of the liquid pipes 901 and 902 is similar to that described above with reference to FIG. 9. In particular, the liquid pipe (e.g., liquid pipe 901) is placed at an equal distance from two adjacent switches (e.g., Q11 and Q13), thereby providing better thermal cooling. In addition, as indicated by the dashed lines in FIG. 10, the left edge of the liquid pipe 903 is aligned with a left edge of the transformer. The right edge of the liquid pipe 904 is aligned with a right edge of the transformer. Such a liquid pipe arrangement can further improve the cooling performance.

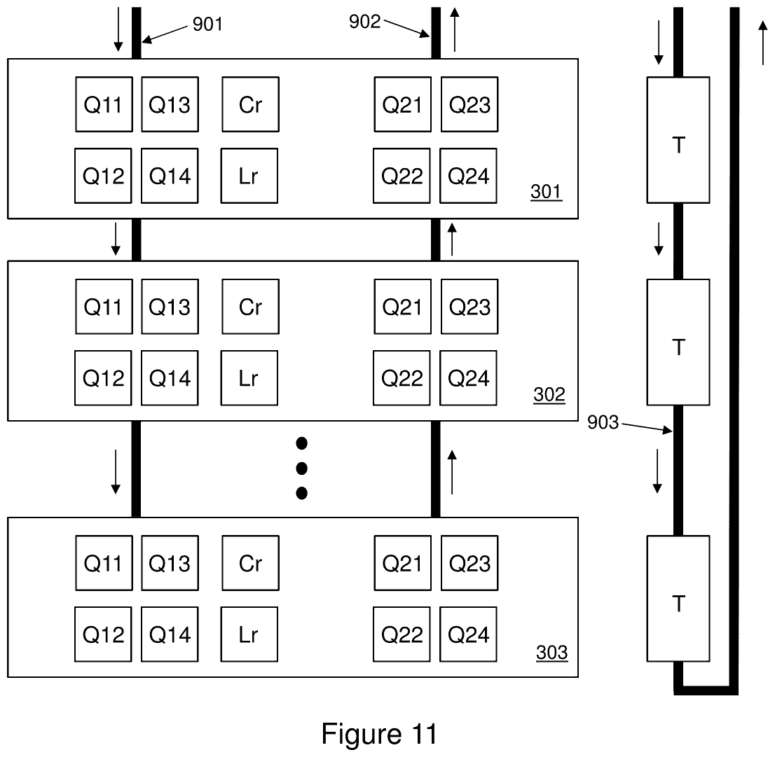

FIG. 11 illustrates a third implementation of cooling a plurality of unregulated LLC power converters in accordance with various embodiments of the present disclosure. The cooling arrangement shown in FIG. 11 is similar to that shown in FIG. 10 except that the liquid pipe 903 is routed through the bodies of the transformers, allowing cooling liquid to circulate within the transformers. In operation, this circulation maintains a substantially uniform temperature across the transformers, thereby enhancing thermal stability and overall performance.

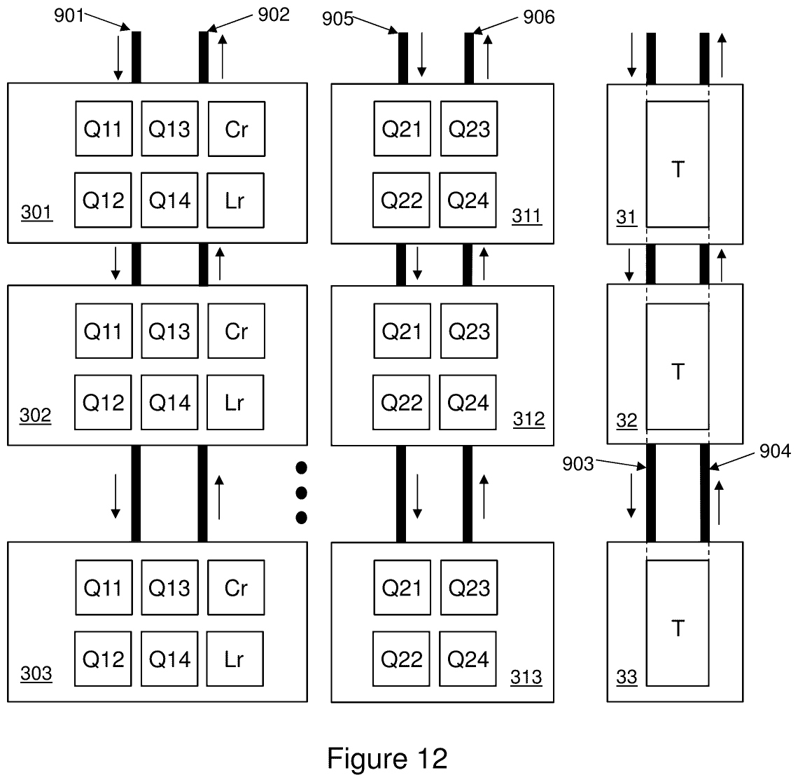

FIG. 12 illustrates a fourth implementation of cooling a plurality of unregulated LLC power converters in accordance with various embodiments of the present disclosure. The cooling arrangement shown in FIG. 12 is similar to that shown in FIG. 10 except that the primary switches and the secondary switches are mounted on two different heat sinks. As shown in FIG. 12, the primary switches and the resonant tank formed by Cr and Lr of the first unregulated LLC power converter are mounted on a heat sink 301. The secondary switches of the first unregulated LLC power converter are mounted on a heat sink 311. Likewise, the primary switches and the resonant tank formed by Cr and Lr of the second unregulated LLC power converter are mounted on a heat sink 302. The secondary switches of the second unregulated LLC power converter are mounted on a heat sink 312. The primary switches and the resonant tank formed by Cr and Lr of the Nth unregulated LLC power converter are mounted on a heat sink 303. The secondary switches of the Nth unregulated LLC power converter are mounted on a heat sink 313.

In operation, liquid circulates through the heat sinks 301, 302 and 303 via liquid pipes 901 and 902 to maintain a first uniform temperature across these heat generation components. Liquid circulates through the heat sinks 311, 312 and 313 via liquid pipes 905 and 906 to maintain a second uniform temperature across these heat generation components. Liquid circulates through the heat sinks 31, 32 and 33 via liquid pipes 903 and 904 to maintain a third uniform temperature across these heat generation components. In some embodiments, the first uniform temperature is equal to the second uniform temperature, and is also equal to the third uniform temperature.

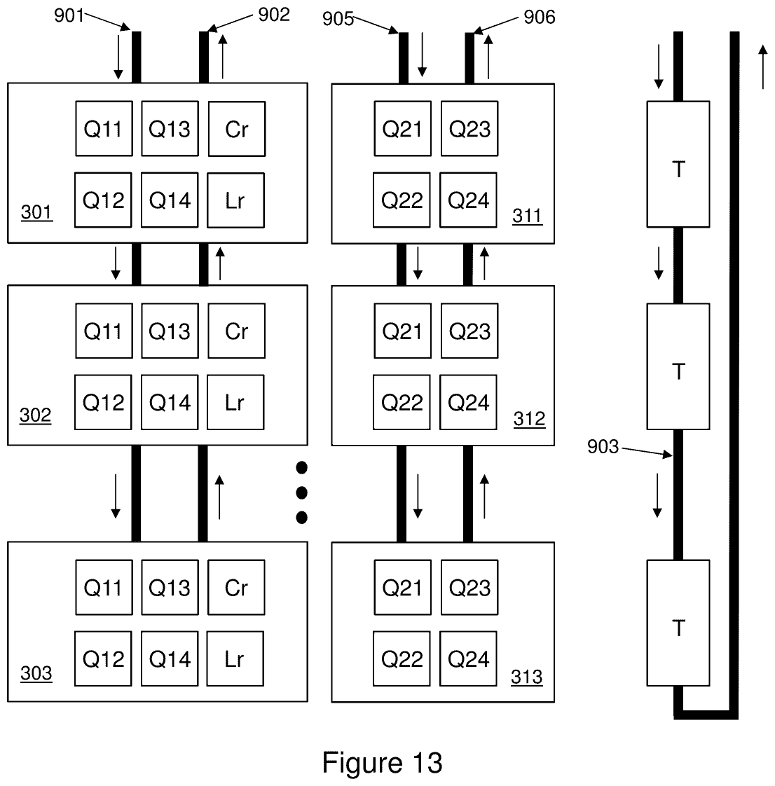

FIG. 13 illustrates a fifth implementation of cooling a plurality of unregulated LLC power converters in accordance with various embodiments of the present disclosure. The cooling arrangement shown in FIG. 13 is similar to that shown in FIG. 12 except that the liquid pipe 903 is routed through the bodies of the transformers, allowing cooling liquid to circulate within the transformers. In operation, this circulation maintains a substantially uniform temperature across the transformers, thereby enhancing thermal stability and overall performance.

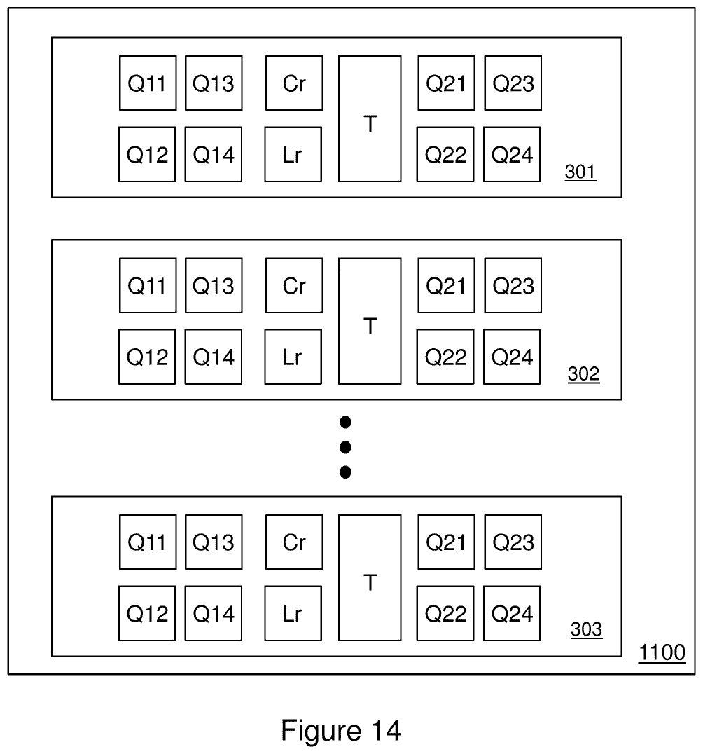

FIG. 14 illustrates a sixth implementation of cooling a plurality of unregulated LLC power converters in accordance with various embodiments of the present disclosure. The heat generation components of the first unregulated power converter are mounted on a first heat sink 301. The heat generation components of the second unregulated power converter are mounted on a second heat sink 302. The heat generation components of the Nth unregulated power converter are mounted on a third heat sink 303. The plurality of unregulated power converters and the associated heat sinks are submerged in a liquid in a container 1100. The liquid in the container 1100 is configured to cool the plurality of the power switches of unregulated power converters to achieve balanced current sharing.

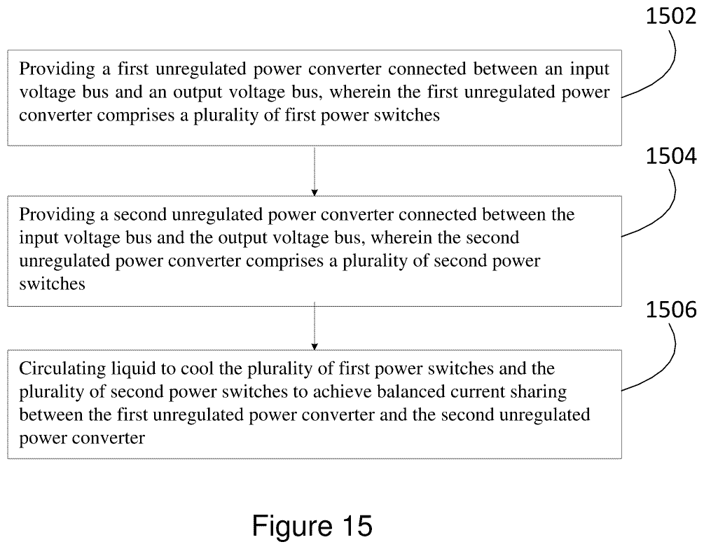

FIG. 15 illustrates a flow chart of a method for cooling the power conversion system shown in FIG. 1 in accordance with various embodiments of the present disclosure. This flowchart shown in FIG. 15 is merely an example, which should not unduly limit the scope of the claims. One of ordinary skill in the art would recognize many variations, alternatives, and modifications. For example, various steps illustrated in FIG. 15 may be added, removed, replaced, rearranged and repeated.

At step 1502, a first unregulated power converter is provided. The first unregulated power converter is connected between an input voltage bus and an output voltage bus, wherein the first unregulated power converter comprises a plurality of first power switches.

At step 1504, a second unregulated power converter is provided. The second unregulated power converter is connected between the input voltage bus and the output voltage bus, wherein the second unregulated power converter comprises a plurality of second power switches.

At step 1506, liquid is circulated to cool the plurality of first power switches and the plurality of second power switches to achieve balanced current sharing between the first unregulated power converter and the second unregulated power converter.

The method further comprises configuring the first unregulated power converter and the second unregulated power converter to operate at a same fixed duty cycle, mounting the plurality of first power switches on a first heat sink, mounting the plurality of second power switches on a second heat sink, and circulating the liquid through the first heat sink and the second heat sink through a plurality of liquid pipes connected between the first heat sink and the second heat sink.

The method further comprises configuring the first unregulated power converter and the second unregulated power converter to operate at a same fixed duty cycle, packaging the first unregulated power converter in a first power module, mounting the first power module on a first heat sink, packaging the second unregulated power converter in a second power module, mounting the second power module on a second heat sink, and circulating the liquid through the first heat sink and the second heat sink through a plurality of liquid pipes connected between the first heat sink and the second heat sink.

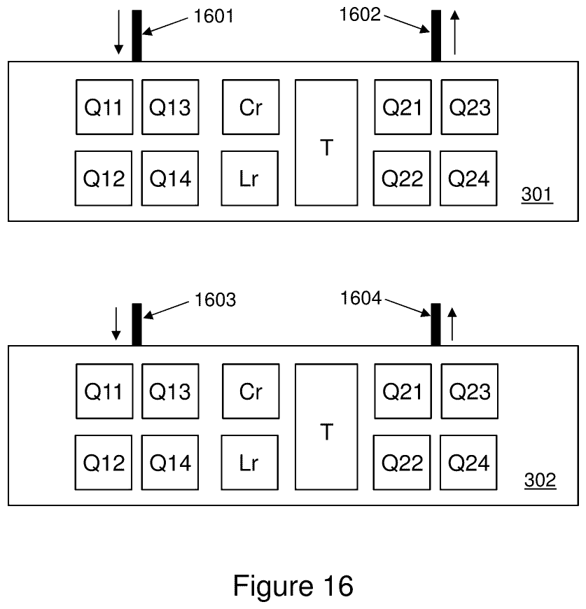

FIG. 16 illustrates an implementation of cooling two unregulated LLC power converters in accordance with various embodiments of the present disclosure. A power conversion system includes a first unregulated power converter and a second unregulated power converter. Each of these two unregulated power converters may be implemented as an LLC resonant converter configured to operate at a fixed duty cycle, for example, 50%. These two unregulated power converters are connected in parallel to provide a combined output current to a load.

The first unregulated power converter includes a plurality of heat generation components including primary power switches, a resonant tank, a transformer and secondary power switches. The heat generation components of the first unregulated power converter are mounted on a first heat sink 301. The first heat sink 301 is thermally coupled to liquid cooling pipes 1601 and 1602, which are configured to circulate cooling liquid at a first controllable flow speed. Similarly, the second unregulated power converter includes a plurality of heat generation components including primary power switches, a resonant tank, a transformer and secondary power switches. The heat generation components of the second unregulated power converter are mounted on a second heat sink 302. The second heat sink 302 is thermally coupled to liquid cooling pipes 1603 and 1604, which are configured to circulate cooling liquid at a second controllable flow speed.

In operation, a current sensing circuit detects a first current flowing through the first unregulated power converter and a second current flowing through the second unregulated power converter. A control circuit compares the magnitudes of the first current and the second current and generates flow control signals to adjust flow speeds of the liquid flowing through the liquid cooling pipes 1601 and 1602, and the liquid flowing through the liquid cooling pipes 1603 and 1604.

In one operational scenario, if the detected first current is greater than the second current, the control circuit reduces the flow speed in the liquid cooling pipes 1601 and 1602, thereby reducing cooling efficiency of the first heat sink 301 and increasing the operating temperature of the power switches of the first unregulated power converter. The increase in temperature causes the on-resistance of the power switches of the first unregulated power converter to increase, which reduces the current drawn by the first unregulated power converter. Concurrently, the flow speed in the liquid cooling pipes 1603 and 1604 is increased, lowering the temperature and on-resistance of the power switches of the second unregulated power converter, thereby increasing current drawn by the second unregulated power converter. This coordinated adjustment balances the current between the two unregulated power converter.

Conversely, if the second current is greater than the first current, the control circuit increases the flow speed in the liquid cooling pipes 1601 and 1602, and reduces the flow speed in the liquid cooling pipes 1603 and 1604, thereby shifting current distribution in the opposite direction until balanced current sharing is achieved.

One advantageous feature of the cooling configuration shown in FIG. 16 is that by adaptively controlling liquid flow speeds, the unregulated power converters achieve substantially equal current sharing across a range of load conditions. More particularly, the disclosed method and system utilize inherent thermal properties of power switches and liquid cooling dynamics to achieve passive current sharing, eliminating the need for complex active current-sharing circuitry. The system is particularly beneficial for high-power applications where liquid cooling is already implemented, such as data center power supplies, electric vehicle chargers, or renewable energy conversion systems.

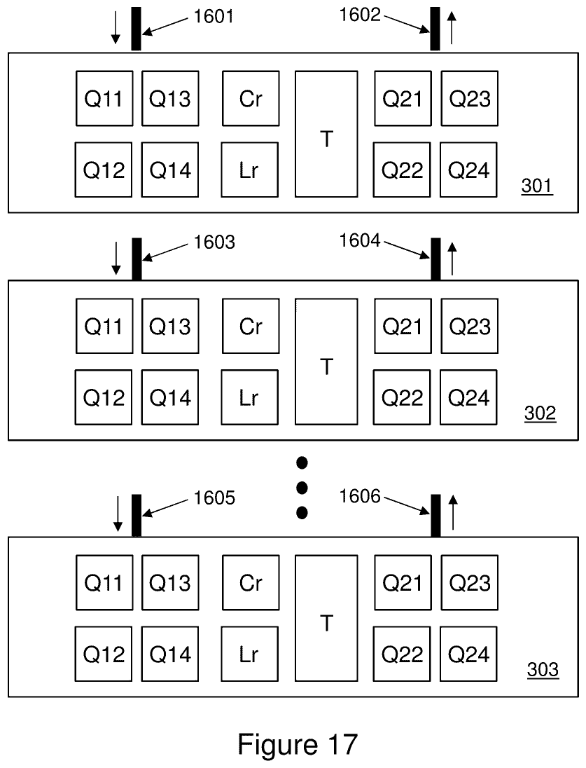

FIG. 17 illustrates an implementation of cooling a plurality of unregulated LLC power converters in accordance with various embodiments of the present disclosure. The power conversion system includes a plurality of unregulated power converters connected in parallel between an input voltage bus and an output voltage bus.

Each of the plurality of converters is configured to operate at a same fixed duty cycle, for example a 50% duty cycle in an LLC resonant topology. Each unregulated power converter comprises primary power switches, a resonant tank, a transformer and secondary power switches mounted on a corresponding heat sink, with each heat sink coupled to liquid cooling pipes having a controllable liquid flow speed.

A current sensing circuit is provided to measure the individual currents flowing through each unregulated power converter. A control circuit receives the current measurements and determines current imbalance among the converters. To address imbalance, the control circuit identifies one converter having a maximum current and another converter having a minimum current. The cooling liquid flow speed in the converter having the maximum current is reduced, thereby increasing its switch temperature and on-resistance, while the cooling liquid flow speed in the converter having the minimum current is increased, thereby reducing its switch temperature and on-resistance.

This adjustment step is performed iteratively. After modifying liquid flow speeds for the converters identified with maximum and minimum currents, the system re-evaluates current distribution among all converters. A new converter with the highest current and a new converter with the lowest current are identified, and the same adjustment process is applied. This iterative process is repeated until the difference between maximum and minimum converter currents is reduced below a predetermined threshold, thereby achieving substantially balanced current sharing across all converters.

By employing this iterative balancing strategy, the power conversion system can dynamically adapt to load changes, device variations, or thermal drift conditions without requiring centralized duty-cycle control or droop compensation circuitry. Because liquid cooling is typically already implemented in high-power power conversion systems, such as large data center power supplies, electric vehicle charging stations, or renewable energy inverters, the disclosed method provides a low-cost and reliable mechanism for balancing currents among multiple parallel unregulated converters.

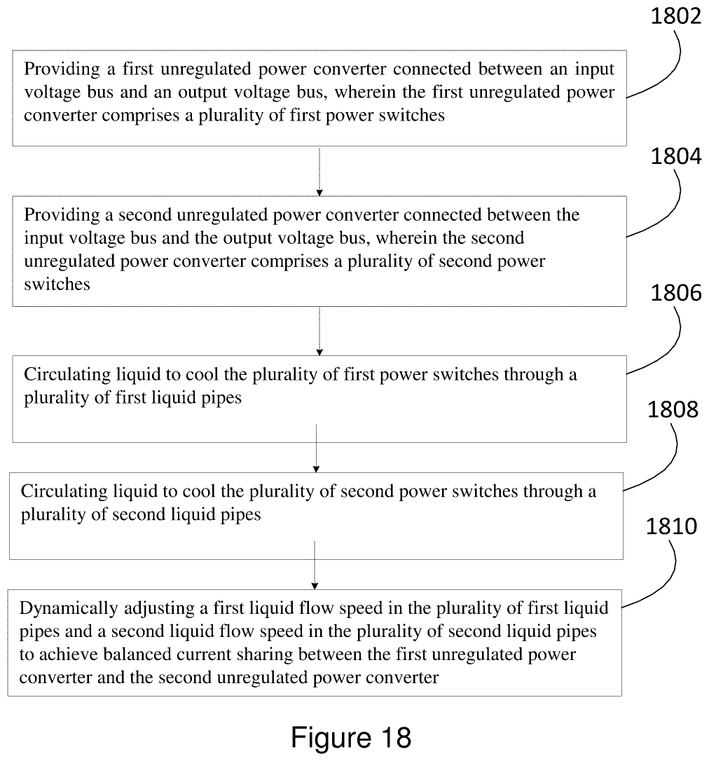

FIG. 18 illustrates a flow chart of a method for cooling the power conversion system shown in FIG. 16 in accordance with various embodiments of the present disclosure. This flowchart shown in FIG. 18 is merely an example, which should not unduly limit the scope of the claims. One of ordinary skill in the art would recognize many variations, alternatives, and modifications. For example, various steps illustrated in FIG. 18 may be added, removed, replaced, rearranged and repeated.

At step 1802, a first unregulated power converter is provided. The first unregulated power converter is connected between an input voltage bus and an output voltage bus, wherein the first unregulated power converter comprises a plurality of first power switches.

At step 1804, a second unregulated power converter is provided. The second unregulated power converter is connected between the input voltage bus and the output voltage bus, wherein the second unregulated power converter comprises a plurality of second power switches.

At step 1806, liquid is circulated to cool the plurality of first power switches through a plurality of first liquid pipes.

At step 1808, liquid is circulated to cool the plurality of second power switches through a plurality of second liquid pipes.

At step 1810, a first liquid flow speed in the plurality of first liquid pipes and a second liquid flow speed in the plurality of second liquid pipes are dynamically adjusted to achieve balanced current sharing between the first unregulated power converter and the second unregulated power converter.

The method further comprises configuring the first unregulated power converter and the second unregulated power converter to operate at a same fixed duty cycle; mounting the plurality of first power switches on a first heat sink; mounting the plurality of second power switches on a second heat sink; detecting a first current flowing through the first unregulated power converter and a second current flowing through the second unregulated power converter; in response to a current level of the first current greater than a current level of the second current, reducing the first liquid flow speed in the plurality of first liquid pipes to increase on-resistance of the plurality of first power switches, and increasing the second liquid flow speed in the plurality of second liquid pipes to reduce on-resistance of the plurality of second power switches, thereby achieving balanced current sharing between the first unregulated power converter and the second unregulated power converter; and in response to the current level of the second current greater than the current level of the first current, increasing the first liquid flow speed in the plurality of first liquid pipes to reduce the on-resistance of the plurality of first power switches, and reducing the second liquid flow speed in the plurality of second liquid pipes to increase the on-resistance of the plurality of second power switches, thereby achieving balanced current sharing between the first unregulated power converter and the second unregulated power converter.

The method further comprises providing a plurality of unregulated power converters connected between the input voltage bus and the output voltage bus, wherein the plurality of unregulated power converters comprises the first unregulated power converter and the second unregulated power converter, and wherein each of the plurality of unregulated power converters comprises a plurality of power switches; configuring the plurality of unregulated power converters to operate at a same fixed duty cycle; mounting power switches of an unregulated power converter of the plurality of unregulated power converters on a corresponding heat sink; detecting currents flowing through the plurality of unregulated power converters; finding an unregulated power converter having a max current and an unregulated power converter having a min current; and reducing a liquid flow speed in a plurality of liquid pipes connected to the unregulated power converter having the max current, and increasing a liquid flow speed in a plurality of liquid pipes connected to the unregulated power converter having the min current, thereby achieving balanced current sharing.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system comprising:
a first unregulated power converter connected between an input voltage bus and an output voltage bus, wherein the first unregulated power converter comprises a plurality of first power switches;
a second unregulated power converter connected between the input voltage bus and the output voltage bus, wherein the second unregulated power converter comprises a plurality of second power switches; and
a liquid cooling system configured to cool the plurality of first power switches and the plurality of second power switches to achieve balanced current sharing between the first unregulated power converter and the second unregulated power converter.

2. The system of claim 1, further comprising:
a first heat sink, wherein the plurality of first power switches is mounted on the first heat sink;
a second heat sink, wherein the plurality of second power switches is mounted on the second heat sink; and
a plurality of liquid pipes connected between the first heat sink and the second heat sink, wherein liquid circulates through the first heat sink and the second heat sink via the plurality of liquid pipes.

3. The system of claim 1, further comprising:
a first heat sink, wherein the first unregulated power converter is packaged in a first power module, and wherein the first power module is mounted on the first heat sink;
a second heat sink, wherein the second unregulated power converter is packaged in a second power module, and wherein the second power module is mounted on the second heat sink; and
a plurality of liquid pipes connected between the first heat sink and the second heat sink, wherein liquid circulates through the first heat sink and the second heat sink via the plurality of liquid pipes.

4. The system of claim 1, further comprising:
a first finger heat sink, wherein the plurality of first power switches is mounted on the first finger heat sink;
a second finger heat sink, wherein the plurality of second power switches is mounted on the second finger heat sink; and
a plurality of liquid pipes connected between the first finger heat sink and the second finger heat sink, wherein liquid circulates through the first finger heat sink and the second finger heat sink via the plurality of liquid pipes.

5. The system of claim 1, further comprising:
a first finger heat sink, wherein the first unregulated power converter is packaged in a first power module, and wherein first power module is mounted on the first finger heat sink;
a second finger heat sink, wherein the second unregulated power converter is packaged in a second power module, and wherein the second power module is mounted on the second finger heat sink; and
a plurality of liquid pipes connected between the first finger heat sink and the second finger heat sink, wherein liquid circulates through the first finger heat sink and the second finger heat sink via the plurality of liquid pipes.

6. The system of claim 1, further comprising:
a finger heat sink, wherein the plurality of first power switches and the plurality of second power switches are mounted on the finger heat sink; and
a plurality of liquid pipes connected to the finger heat sink, wherein liquid circulates through the finger heat sink via the plurality of liquid pipes.

7. The system of claim 1, further comprising:
a finger heat sink, wherein:
the first unregulated power converter is packaged in a first power module;
the second unregulated power converter is packaged in a second power module; and
the first power module and the second power module are mounted on the finger heat sink; and
a plurality of liquid pipes connected to the finger heat sink, wherein liquid circulates through the finger heat sink via the plurality of liquid pipes.

8. The system of claim 1, wherein:
the first unregulated power converter is a first inductor-inductor-capacitor (LLC) resonant converter configured to operate at a fixed duty cycle, wherein the first LLC resonant converter comprises a plurality of first primary switches, a first resonant tank, a first transformer and a plurality of first secondary switches; and
the second unregulated power converter is a second LLC resonant converter configured to operate at the fixed duty cycle, wherein the second LLC resonant converter comprises a plurality of second primary switches, a second resonant tank, a second transformer and a plurality of second secondary switches.

9. The system of claim 8, further comprising:
a first heat sink, wherein the plurality of first primary switches, the first resonant tank, the first transformer and the plurality of first secondary switches are mounted on the first heat sink;
a second heat sink, wherein the plurality of second primary switches, the second resonant tank, the second transformer and the plurality of second secondary switches are mounted on the second heat sink; and
a plurality of liquid pipes connected between the first heat sink and the second heat sink, wherein liquid circulates through the first heat sink and the second heat sink via the plurality of liquid pipes, and wherein:
a first liquid pipe of the plurality of liquid pipes is placed at a first equal distance from two adjacent first primary switches; and
a second liquid pipe of the plurality of liquid pipes is placed at a second equal distance from two adjacent first secondary switches.

10. The system of claim 8, further comprising:
a first heat sink, wherein the plurality of first primary switches, the first resonant tank and the plurality of first secondary switches are mounted on the first heat sink;
a second heat sink, wherein the plurality of second primary switches, the second resonant tank and the plurality of second secondary switches are mounted on the second heat sink;
a plurality of first liquid pipes connected between the first heat sink and the second heat sink, wherein liquid circulates through the first heat sink and the second heat sink via the plurality of first liquid pipes;
a first transformer heat sink, wherein the first transformer is mounted on the first transformer heat sink;
a second transformer heat sink, wherein the second transformer is mounted on the second transformer heat sink; and
a plurality of second liquid pipes connected between the first transformer heat sink and the second transformer heat sink, wherein liquid circulates through the first transformer heat sink and the second transformer heat sink via the plurality of second liquid pipes, and wherein:
a first liquid pipe of the plurality of first liquid pipes is placed at a first equal distance from two adjacent first primary switches;
a second liquid pipe of the plurality of first liquid pipes is placed at a second equal distance from two adjacent first secondary switches;
a left edge of the first liquid pipe of the plurality of second liquid pipes is aligned with a left edge of the first transformer; and
a right edge of th second liquid pipe of the plurality of second liquid pipes is aligned with a right edge of the first transformer.

11. The system of claim 8, further comprising:
a first heat sink, wherein the plurality of first primary switches, the first resonant tank and the plurality of first secondary switches are mounted on the first heat sink;
a second heat sink, wherein the plurality of second primary switches, the second resonant tank and the plurality of second secondary switches are mounted on the second heat sink;
a plurality of first liquid pipes connected between the first heat sink and the second heat sink, wherein liquid circulates through the first heat sink and the second heat sink via the plurality of first liquid pipes; and
a plurality of second liquid pipes connected to the first transformer and the second transformer, wherein liquid circulates through the first transformer and the second transformer via the plurality of second liquid pipes.

12. The system of claim 8, further comprising:
a first primary heat sink, wherein the plurality of first primary switches and the first resonant tank are mounted on the first primary heat sink;
a first secondary heat sink, wherein the plurality of first secondary switches is mounted on the first secondary heat sink;
a second primary heat sink, wherein the plurality of second primary switches and the second resonant tank are mounted on the second primary heat sink;
a second secondary heat sink, wherein the plurality of second secondary switches is mounted on the second secondary heat sink;
a plurality of primary liquid pipes connected between the first primary heat sink and the second primary heat sink, wherein liquid circulates through the first primary heat sink and the second primary heat sink via the plurality of primary liquid pipes;
a plurality of secondary liquid pipes connected between the first secondary heat sink and the second secondary heat sink, wherein liquid circulates through the first secondary heat sink and the second secondary heat sink via the plurality of secondary liquid pipes;
a first transformer heat sink, wherein the first transformer is mounted on the first transformer heat sink;
a second transformer heat sink, wherein the second transformer is mounted on the second transformer heat sink; and
a plurality of transformer liquid pipes connected between the first transformer heat sink and the second transformer heat sink, wherein liquid circulates through the first transformer heat sink and the second transformer heat sink via the plurality of transformer liquid pipes.

13. The system of claim 8, further comprising:
a first primary heat sink, wherein the plurality of first primary switches and the first resonant tank are mounted on the first primary heat sink;
a first secondary heat sink, wherein the plurality of first secondary switches is mounted on the first secondary heat sink;
a second primary heat sink, wherein the plurality of second primary switches and the second resonant tank are mounted on the second primary heat sink;
a second secondary heat sink, wherein the plurality of second secondary switches is mounted on the second secondary heat sink;
a plurality of primary liquid pipes connected between the first primary heat sink and the second primary heat sink, wherein liquid circulates through the first primary heat sink and the second primary heat sink via the plurality of primary liquid pipes;
a plurality of secondary liquid pipes connected between the first secondary heat sink and the second secondary heat sink, wherein liquid circulates through the first secondary heat sink and the second secondary heat sink via the plurality of secondary liquid pipes; and
a plurality of transformer liquid pipes connected to the first transformer and the second transformer, wherein liquid circulates through the first transformer and the second transformer via the plurality of transformer liquid pipes.

14. The system of claim 1, further comprising:
a plurality of unregulated power converters connected between the input voltage bus and the output voltage bus, wherein each of the plurality of unregulated power converters comprises a plurality of power switches, and wherein the power switches of the plurality of unregulated power converters are submerged in a liquid in a container, and wherein the liquid is configured to cool the power switches of the plurality of unregulated power converters to achieve balanced current sharing among the plurality of unregulated power converters connected between the input voltage bus and the output voltage bus.

15. A method comprising:
providing a first unregulated power converter connected between an input voltage bus and an output voltage bus, wherein the first unregulated power converter comprises a plurality of first power switches;
providing a second unregulated power converter connected between the input voltage bus and the output voltage bus, wherein the second unregulated power converter comprises a plurality of second power switches; and
circulating liquid to cool the plurality of first power switches and the plurality of second power switches to achieve balanced current sharing between the first unregulated power converter and the second unregulated power converter.

16. The method of claim 15, further comprising:
configuring the first unregulated power converter and the second unregulated power converter to operate at a same fixed duty cycle;
mounting the plurality of first power switches on a first heat sink;
mounting the plurality of second power switches on a second heat sink; and
circulating the liquid through the first heat sink and the second heat sink through a plurality of liquid pipes connected between the first heat sink and the second heat sink.

17. The method of claim 15, further comprising:
configuring the first unregulated power converter and the second unregulated power converter to operate at a same fixed duty cycle;
packaging the first unregulated power converter in a first power module;
mounting the first power module on a first heat sink;
packaging the second unregulated power converter in a second power module;
mounting the second power module on a second heat sink; and
circulating the liquid through the first heat sink and the second heat sink through a plurality of liquid pipes connected between the first heat sink and the second heat sink.

18. A method comprising:
providing a first unregulated power converter connected between an input voltage bus and an output voltage bus, wherein the first unregulated power converter comprises a plurality of first power switches;
providing a second unregulated power converter connected between the input voltage bus and the output voltage bus, wherein the second unregulated power converter comprises a plurality of second power switches;
circulating liquid to cool the plurality of first power switches through a plurality of first liquid pipes;
circulating liquid to cool the plurality of second power switches through a plurality of second liquid pipes; and
dynamically adjusting a first liquid flow speed in the plurality of first liquid pipes and a second liquid flow speed in the plurality of second liquid pipes to achieve balanced current sharing between the first unregulated power converter and the second unregulated power converter.

19. The method of claim 18, further comprising:
configuring the first unregulated power converter and the second unregulated power converter to operate at a same fixed duty cycle;
mounting the plurality of first power switches on a first heat sink;
mounting the plurality of second power switches on a second heat sink;
detecting a first current flowing through the first unregulated power converter and a second current flowing through the second unregulated power converter;
in response to a current level of the first current greater than a current level of the second current, reducing the first liquid flow speed in the plurality of first liquid pipes to increase on-resistance of the plurality of first power switches, and increasing the second liquid flow speed in the plurality of second liquid pipes to reduce on-resistance of the plurality of second power switches, thereby achieving balanced current sharing between the first unregulated power converter and the second unregulated power converter; and
in response to the current level of the second current greater than the current level of the first current, increasing the first liquid flow speed in the plurality of first liquid pipes to reduce the on-resistance of the plurality of first power switches, and reducing the second liquid flow speed in the plurality of second liquid pipes to increase the on-resistance of the plurality of second power switches, thereby achieving balanced current sharing between the first unregulated power converter and the second unregulated power converter.

20. The method of claim 18, further comprising:
providing a plurality of unregulated power converters connected between the input voltage bus and the output voltage bus, wherein the plurality of unregulated power converters comprises the first unregulated power converter and the second unregulated power converter, and wherein each of the plurality of unregulated power converters comprises a plurality of power switches;
configuring the plurality of unregulated power converters to operate at a same fixed duty cycle;
mounting power switches of an unregulated power converter of the plurality of unregulated power converters on a corresponding heat sink;
detecting currents flowing through the plurality of unregulated power converters;
finding an unregulated power converter having a maximum current and an unregulated power converter having a minimum current; and
reducing a liquid flow speed in a plurality of liquid pipes connected to the unregulated power converter having the maximum current, and increasing a liquid flow speed in a plurality of liquid pipes connected to the unregulated power converter having the minimum current, thereby achieving balanced current sharing.
